(19) United States
(12) Patent Application Publication
(10) Pub. No.: US 2013/0181253 A1
(43) Pub. Date: Jul. 18, 2013

(54) SEMICONDUCTOR STRUCTURE AND MANUFACTURING METHOD THEREOF

(71) Applicants: Tsung-Yi Huang, Hsinchu City (TW); Chien-Wei Chiu, Beigang Township (TW); Chien-Hao Huang, Magong City (TW)

(72) Inventors: Tsung-Yi Huang, Hsinchu City (TW); Chien-Wei Chiu, Beigang Township (TW); Chien-Hao Huang, Magong City (TW)

(73) Assignee: Richtek Technology Corporation, R.O.C.

(21) Appl. No.: 13/353,053

(22) Filed: Jan. 18, 2012

(51) Int. Cl. H01L 29/72; H01L 21/331

(52) U.S. Cl. 257/139; 438/138; 257/E29.183; 257/E21.384

(57) ABSTRACT

The present invention discloses a semiconductor structure and a manufacturing method thereof. The semiconductor structure is formed in a first conductive type substrate, which has an upper surface. The semiconductor structure includes: a protected device, at least a buried trench, and at least a doped region. The protected device is formed in the substrate. The buried trench is formed below the upper surface with a first depth, and the buried trench surrounds the protected device from top view. The doped region is formed below the upper surface with a second depth, and the doped region surrounds the buried trench from top view. The second depth is not less than the first depth.

### BACKGROUND OF THE INVENTION

1. Field of Invention

The present invention relates to a semiconductor structure and a manufacturing method of a semiconductor structure; particularly, it relates to such semiconductor structure and manufacturing method wherein the breakdown voltage of a device is increased.

2. Description of Related Art

FIG. 3 shows simulated level contours of a prior art guard ring in a reversely biased condition. The function of the guard ring is to protect a device (not shown) surrounded by the guard ring, and the guard ring is typically coupled to ground or floating. More specifically, when the device is in operation, and a well surrounding the device is reversely biased, the level contours in a depletion region of the surrounding well will form dense peaks outside the device, and the electrical field will be unbearable by the device if it is not protected by the guard ring. Therefore, the breakdown voltage of a device without the guard ring is relatively lower.

Referring to FIG. 3, the prior art guard ring includes a buried trench 23 and a doped region 25, which mitigate the peaks of the level contours outside the protected device such that the electrical field is decreased, and the operation voltage which the protected device can sustain is increased, i.e., the breakdown voltage is increased.

However, as the size of a device becomes smaller and the applications of the device become broader, it becomes more difficult to keep the breakdown voltage of the protected device although with the guard ring.

In view of above, to overcome the drawback in the prior art, the present invention proposes a semiconductor structure and a manufacturing method thereof which provide a higher breakdown voltage so that the protected device may have a broader application range, in which additional manufacturing process steps are not required and the device area is not increased, such that the protected device can be integrated with a low voltage device and manufactured by common manufacturing process steps.

### SUMMARY OF THE INVENTION

A first objective of the present invention is to provide a semiconductor structure.

A second objective of the present invention is to provide a manufacturing method of a semiconductor structure.

To achieve the objectives mentioned above, from one perspective, the present invention provides a semiconductor structure formed in a first conductive type substrate, wherein the first conductive type substrate has an upper surface, the semiconductor structure comprising: a protected device, which is formed in the first conductive type substrate; at least a first buried trench, which is formed below the upper surface and surrounds the protected device from top view, the first buried trench having a first depth from the upper surface downward; and at least a doped region, which is formed below the upper surface and surrounds the first buried trench from top view, the doped region being of a second conductive type and having a second depth from the upper surface downward; wherein the second depth is not less than the first depth.

From another perspective, the present invention provides a manufacturing method of a semiconductor structure, including: providing a first conductive type substrate, wherein the first conductive type substrate has an upper surface; forming a protected device in the first conductive type substrate; forming at least a first buried trench below the upper surface, which surrounds the protected device from top view, the first buried trench having a first depth from the upper surface downward; and forming at least a doped region below the upper surface, which surrounds the first buried trench from top view, the doped region being of a second conductive type and having a second depth from the upper surface downward; wherein the second depth is not less than the first depth.

In one embodiment, the protected device preferably includes a high voltage device.

In the aforementioned embodiment, the semiconductor structure preferably further includes a second conductive type substrate, which is located below the first conductive type substrate, wherein the high voltage device is an insulate gate bipolar transistor (IGBT), and the second conductive type substrate is electrically connected to a collector of the IGBT.

In another embodiment, the doped region preferably includes at least a second buried trench, which is formed below the upper surface and surrounds the first buried trench from top view; and at least a wrapping doped region, which is formed outside and surrounding the second buried trench in the first conductive type substrate below the upper surface.

In the aforementioned embodiment, the second buried trench and the first buried trench are preferably formed by same process steps, and the wrapping doped region is preferably formed by an ion implantation process step which implants accelerated ions by different angles with respect to the first conductive type substrate.

The objectives, technical details, features, and effects of the present invention will be better understood with regard to the detailed description of the embodiments below.

### BRIEF DESCRIPTION OF THE DRAWINGS

FIGS. 1A-1F show a first embodiment of the present invention.

FIGS. 2A-2C show a second embodiment of the present invention.

FIGS. 3, 4, and 5 show three simulated level contour maps of three semiconductor structures (guard rings) having different ratios of depths d1 and d2 in a reversely biased condition, respectively.

FIG. 6 shows a more specific embodiment of the protected device in the semiconductor structure of the present invention.

### DESCRIPTION OF THE PREFERRED EMBODIMENTS

The drawings as referred to throughout the description of the present invention are for illustration only, to show the interrelations between the regions and the process steps, but not drawn according to actual scale.

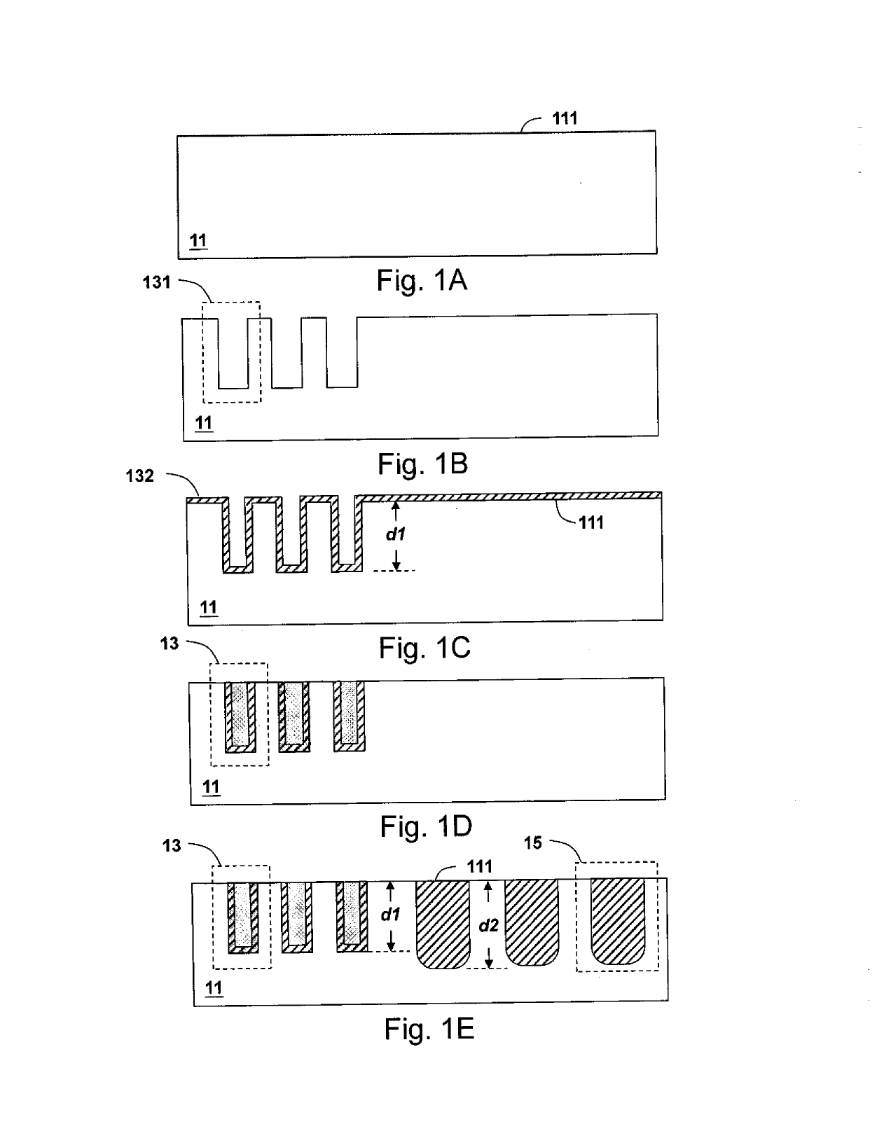

FIGS. 1A-1F show a first embodiment of the present invention. FIGS. 1A-1E are schematic cross-section diagrams showing a manufacturing flow according to this embodiment. FIG. 1F shows a top view of the semiconductor structure of this embodiment. As shown in FIG. 1A, first, a substrate 11 is provided, which is for example but not limited to an N-type epitaxial layer formed on a P-type silicon substrate (not shown). Next, trenches 131 are formed below an upper surface 111 of the substrate 11 as shown in FIG. 1B. The trenches 131 are formed by for example but not limited to process steps for forming shallow trench isolation (STI, not shown) in the same substrate 11. In this embodiment, each of the trenches 131 is of a substantially annular shape from top view (as referring to FIG. 1F). Next, as shown in FIG. 1C, an oxide layer 132 is formed on the upper surface 111 of the substrate 11, such that an isolation layer is formed on side walls and bottoms of the trenches 131. The trenches 131 have a depth d1 measured from the upper surface 111 of the substrate 11, as shown in the figure. Next, for example, a polysilicon material such as P-doped or N-doped is deposited in the trenches 131 which have been covered with the oxide layer 132, to form buried trenches 13 as shown in FIG. 1D.

Next, a mask which is formed for example by a lithography process, defines a region (not shown) in which impurities are to be implanted. At least one annular doped region 15 (as referring to FIG. 1F) is formed by an ion implantation process which implants P-type impurities to the defined region in the form of accelerated ions. The one or more doped regions 15 are located below the upper surface 111 of the substrate 11 as shown in FIG. 1E. The doped regions 15 have a depth d2 measured from the upper surface 111 of the substrate 11, as shown in the figure. Note that the depth d2 is not less than the aforementioned depth d1.

FIG. 1F shows a top view of the semiconductor structure of the first embodiment. As shown in the figure, the multiple annular buried trenches 13 surround a protected device 17, and the multiple annular doped regions 15 surround the buried trenches 13. The protected device 17 is for example but not limited to a high voltage device, and the high voltage device is for example but not limited to an insulate gate bipolar transistor (IGBT). Note that the cross-section views shown in FIGS. 1A-1E are cross-section views taken from a cross-section line AA′ shown in FIG. 1F.

One important feature of the present invention is that the depth d2 is not less than the depth d1. From the cross-section view FIG. 1E, a preferred embodiment is that the depth d2 is larger than the depth d1. This arrangement has the advantage that the protected device has better characteristics, because the present invention enhances the breakdown voltage of the protected device 17.

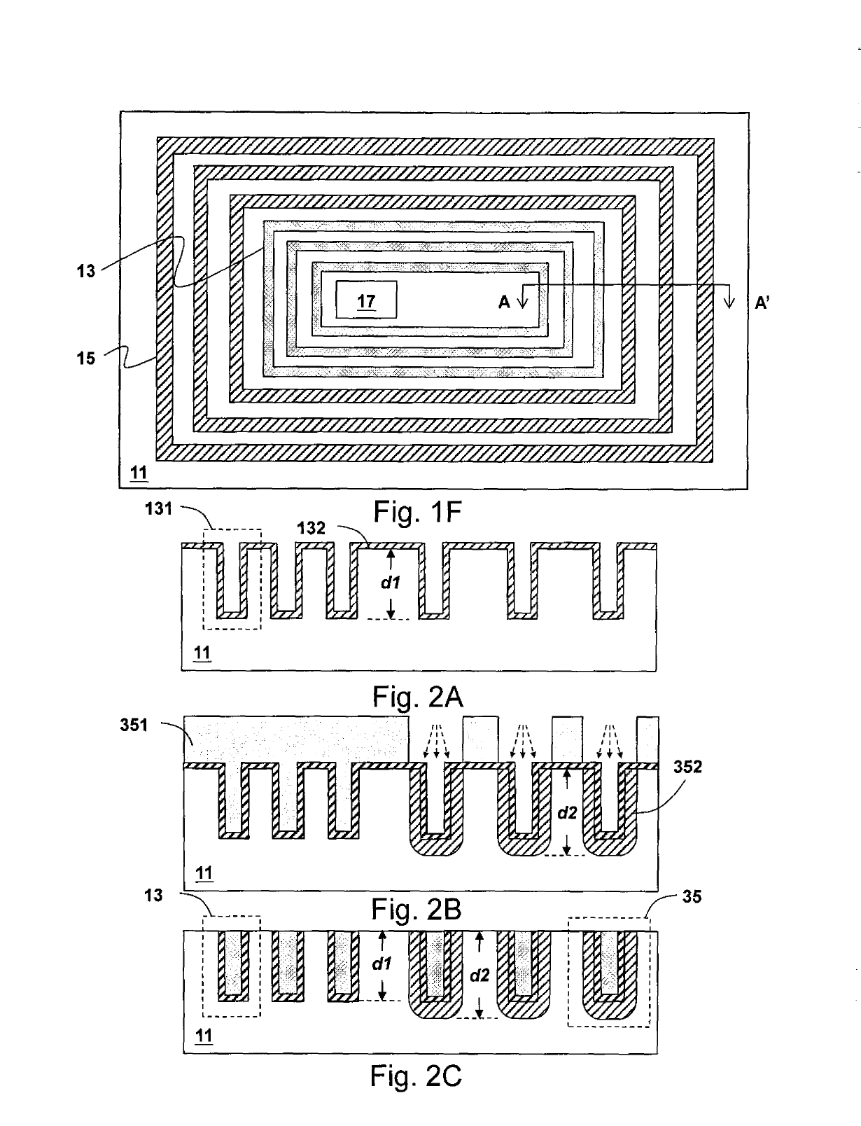

FIGS. 2A-2C show a second embodiment of the present invention. As shown in FIG. 2A, a substrate 11 is first provided, which is for example but not limited to an N-type epitaxial layer formed on a P-type silicon substrate (not shown). Next, at least one trench 131 is formed below the upper surface 111 of the substrate 11 as shown in FIG. 2A. The trenches 131 are formed by for example but not limited to process steps which form shallow trench isolation (STI, not shown) in the same substrate 11. In this embodiment, each of the trenches 131 is of a substantially annular shape from top view. Next, an oxide layer 132 is formed on the upper surface 111 of the substrate 11, such that an isolation layer is formed on side walls and bottoms of the trenches 131. The trenches 131 have the depth d1 measured from the upper surface 111 of the substrate 11, as shown in the figure. Next, a photo-resist layer 351, which is formed by a lithography process, defines a region in which impurities are to be implanted. At least one wrapping doped region 352 is formed by an ion implantation process which implants P-type impurities to the defined region in the form of accelerated ions. The one or more wrapping doped regions 352 are located below the upper surface 111 of the substrate 11 as shown in FIG. 2B. The wrapping doped region 352 has a depth d2 measured from the upper surface 111 of the substrate 11 as shown in FIG. 2B. Note that the depth d2 is not less than the aforementioned depth d1. Next, after the photo-resist layer 351 removed, a polysilicon material such as P-doped or N-doped is deposited in the trenches 131 which have been covered with the oxide layer 132, to form buried trenches 13 and 35 as shown in FIG. 2C.

The second embodiment is different from the first embodiment in the wrapping doped region 352 as compared with the doped region 15. The wrapping doped region 352 is located outside the trenches 131, to provide P-type impurities surrounding the trenches 131. Such arrangement has the advantage that the accelerated ions in the ion implantation process do not need to penetrate a relatively thicker substrate as compared with forming the doped region 15. However, in forming the wrapping doped region 352, the ion implantation process may need to implant impurities by different angles, as indicated by the dashed arrow lines shown in FIG. 2B.

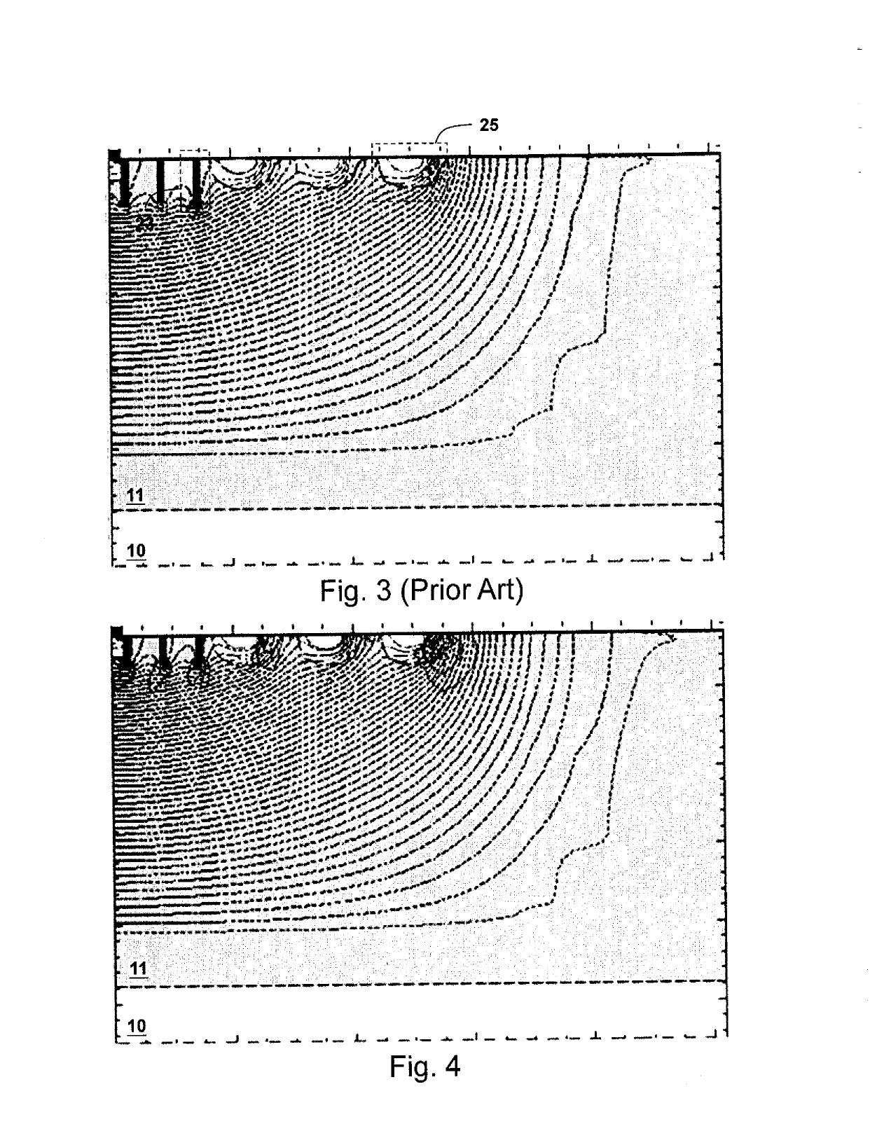

Compared to the prior art, the level contours of the first embodiment and the second embodiment have lower local densities. It indicates that the electrical fields of the embodiments of the present invention are relatively lower under the same operation conditions, so the protected device of the present invention may sustain a relatively higher operation voltage, i.e., the breakdown voltage of the present invention is relatively higher. FIGS. 3, 4, and 5 show simulated level contour maps of three semiconductor structures (guard rings) with different ratios between the depth d1 and d2 in reversely biased conditions. FIGS. 3, 4, and 5 respectively show the cases where the depth d1 is larger than (prior art), equal to (the present invention), and less than (the present invention) d2 of the prior art. As shown by the simulation results, the breakdown voltages of FIGS. 3, 4 and 5 are 408V, 496V, and 507V respectively. It is obvious that the breakdown voltage is increased by the present invention.

Referring to FIGS. 3, 4, and 5, they show that the densities of the level contours of the present invention are lower than that of the prior art. This indicates that, in the same operation conditions, the electrical fields of the present invention are relatively lower in a reversely biased condition when the P-type substrate 10 is electrically connected to a negative voltage and the N-type substrate 11 is electrically connected to a positive voltage, and the present invention can sustain a higher operation voltage with a higher breakdown voltage.

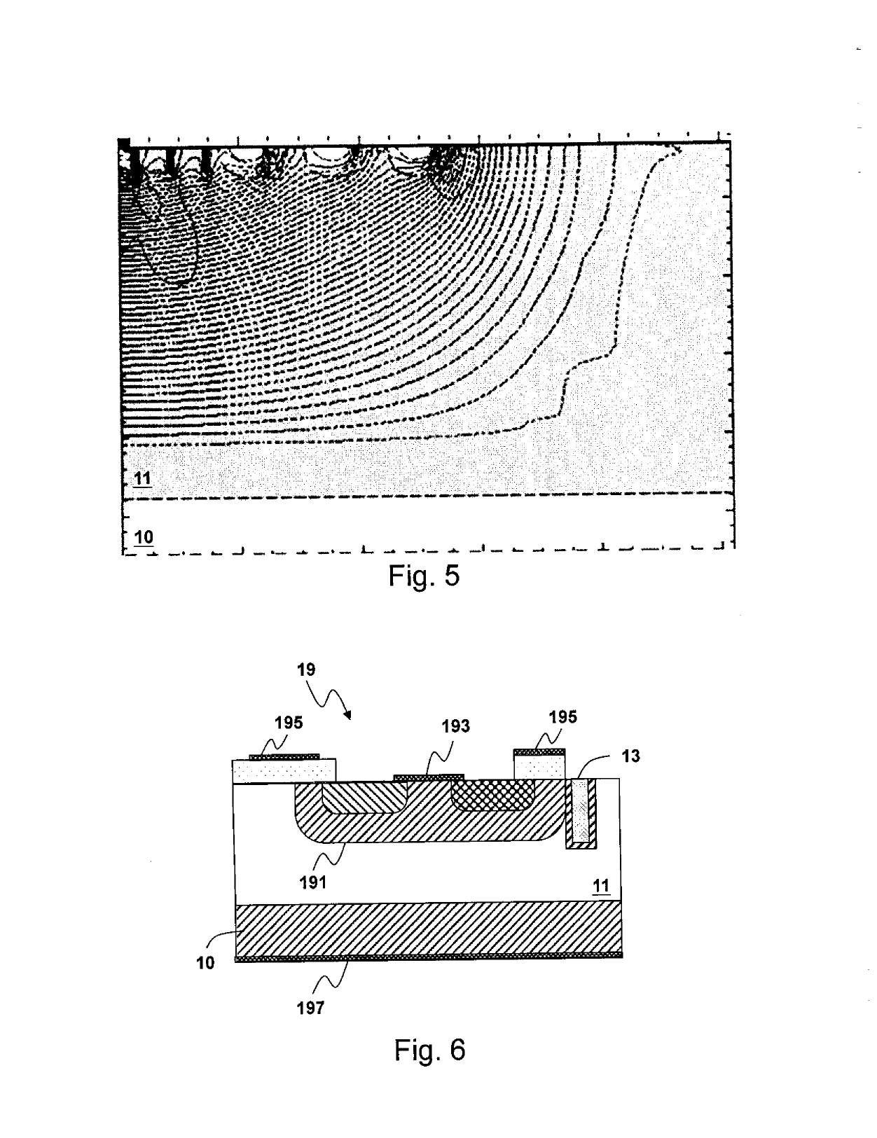

FIG. 6 shows an embodiment of the protected device in the semiconductor structure of the present invention. As shown in the figure, the protected device is for example but not limited to a high voltage device, such as an N-channel IGBT 19. The IGBT 19 includes a P-type body 191, an emitter 193, a gate 195, and a collector 197. The P-type substrate 10 is electrically connected to the collector 197 of the IGBT 19. When the IGBT 19 operates in a reversely biased condition, i.e., when the collector 197 is electrically connected to a negative voltage and the N-type substrate 11 is electrically connected to a positive voltage, the breakdown voltage of the device can be increased if it has the guard ring of the present invention.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristics of the device, such as a deep well, etc., can be added. For another example, the lithography step described in the above can be replaced by electron beam lithography, X-ray lithography, etc. For yet another example, although the buried trench 13 and the buried trench 35 of the second embodiment are preferably formed by the same process steps, they may be formed by different process steps, with the depth d2 not less than the depth d1. For another example, the wrapping doped region 352 and the doped region 15 may be P-type, and in this case the conductivities of the doped regions should be reversed, that is, the P-type regions should be replaced by N-type regions and the N-type regions should be replaced by P-type regions. In view of the foregoing, the spirit of the present invention should cover all such and other modifications and variations, which should be interpreted to fall within the scope of the following claims and their equivalents.

What is claimed is:

1. A semiconductor structure, which is formed in a first conductive type substrate, wherein the first conductive type substrate has an upper surface, the semiconductor structure comprising:
a protected device, which is formed in the first conductive type substrate;
at least a first buried trench, which is formed below the upper surface and surrounds the protected device from top view, the first buried trench having a first depth from the upper surface downward; and
at least a doped region, which is formed below the upper surface and surrounds the first buried trench from top view, the doped region being of a second conductive type and having a second depth from the upper surface downward;
wherein the second depth is not less than the first depth.

2. The semiconductor structure of claim 1, wherein the protected device includes a high voltage device.

3. The semiconductor structure of claim 2, further includes a second conductive type substrate located below the first conductive type substrate, wherein the high voltage device is an insulate gate bipolar transistor (IGBT), and the second conductive type substrate is electrically connected to a collector of the IGBT.

4. The semiconductor structure of claim 1, wherein the doped region includes:
at least a second buried trench, which is formed below the upper surface and surrounds the first buried trench from top view; and
at least a wrapping doped region which is formed outside and surrounds the second buried trench in the first conductive type substrate below the upper surface.

5. The semiconductor structure of claim 4, wherein the second buried trench and the first buried trench are formed by same process steps, and the wrapping doped region is formed by an ion implantation process step which implants accelerated ions by different angles with respect to the first conductive type substrate.

6. A manufacturing method of a semiconductor structure, comprising:
providing a first conductive type substrate, wherein the first conductive type substrate has an upper surface;
forming a protected device in the first conductive type substrate;
forming at least a first buried trench below the upper surface, which surrounds the protected device from top view, and has a first depth from the upper surface downward; and
forming at least a doped region below the upper surface, which surrounds the first buried trench from top view, the doped region being of a second conductive type and having a second depth from the upper surface downward;
wherein the second depth is not less than the first depth.

7. The manufacturing method of claim 6, wherein he protected device includes a high voltage device.

8. The manufacturing method of claim 7, further including: providing a second conductive type substrate below the first conductive type substrate, wherein the high voltage device is an insulate gate bipolar transistor (IGBT), and the second conductive type substrate is electrically connected to a collector of the IGBT.

9. The manufacturing method of claim 6, wherein the step of forming at least a doped region includes:
forming at least a second buried trench below the upper surface and surrounding the first buried trench from top view; and
forming at least a wrapping doped region outside and surrounding the second buried trench in the first conductive type substrate below the upper surface.

10. The manufacturing method of claim 9, wherein the second buried trench and the first buried trench are formed by same process steps, and the wrapping doped region is formed by an ion implantation process step which implants accelerated ions by different angles with respect to the first conductive type substrate.
